(19) United States
(12) Patent Application Publication
(10) Pub. No.: US 2008/0135984 A1
(43) Pub. Date: Jun. 12, 2008

(54) SEMICONDUCTOR DEVICE

(76) Inventor: Yong-Ho Oh, Incheon (KR)

Correspondence Address: SHERR & NOURSE, PLLC, 620 HERNDON PARKWAY, SUITE 200, HERNDON, VA, 20170, US

(21) Appl. No.: 11/932,206

(22) Filed: Oct. 31, 2007

(30) Foreign Application Priority Data
Dec. 12, 2006 (KR) 10-2006-0126088

(51) Int. Cl. H01L 21/469; H01L 29/51

(52) U.S. Cl. 257/640; 438/763; 257/E29.165; 257/E21.487

(57) ABSTRACT

Embodiments relate to a Metal-Oxide Semiconductor Field Effect Transistor (MOSFET) and a method of fabricating a MOSFET. According to embodiments, a method of forming a MOSFET may include forming a first gate insulating layer on a semiconductor substrate, nitrifying the first gate insulating layer, forming a second gate insulating layer on the first gate insulating layer, injecting fluorine ions into the second gate insulating layer, and diffusing the fluorine ions into the first gate insulating layer.

The present application claims priority under 35 U.S.C. 119 and 35 U.S.C. 365 to Korean Patent Application No. 10-2006-0126088 (filed on Dec. 12, 2006), which is hereby incorporated by reference in its entirety.

### BACKGROUND

A MOSFET (Metal Oxide Silicon Field Effect Transistor) may include a gate electrode, a source electrode, a drain electrode, and a dielectric layer inserted between the gate electrode and the source/drain electrode. The MOSFET may be constructed on a semiconductor substrate.

To provide for down-sizing, light-weight, and slimness of semiconductor devices, a size of MOSFET may need to be scaled down. The scale-down of such transistors may reduce an effective channel length of a gate electrode, which may in turn cause a short-channel effect. The short channel effect may degrade a punch-through characteristic between the source and drain.

In a device below 90 nm, the rapid increase of gate leakage current may limit the use of a SiO₂ based gate insulating layer. It may be important to develop an insulating substance having a high dielectric constant (high-k), such as HfO₂ and Al₂O₃, for a gate insulating layer. In particular, a gate insulating layer of HfO₂-series insulating substance having good thermal stability may be beneficial.

As compared to a gate insulating layer of SiO₂, however, a gate insulating layer of the high dielectric constant insulating substance may have more traps on an interface with a silicon substrate. Moreover, it may have poor roughness and the like, which may reduce carrier mobility speed of charge. This may degrade device capacity and reliability.

### SUMMARY

Embodiments relate to a semiconductor device and a method of fabricating a semiconductor device. Embodiments relate to a Metal-Oxide Semiconductor Field Effect Transistor (MOSFET) and a method of fabricating a MOSFET.

Embodiments relate to a MOSFET and a method of fabricating a MOSFET, by which gate insulating layer reliability and device operation characteristics may be enhanced by performing an annealing process on a gate insulating layer of a high dielectric constant.

According to embodiments, a method of fabricating a semiconductor device may include forming a first gate insulating layer on a semiconductor substrate, nitrifying the first gate insulating layer, forming a second gate insulating layer on the first gate insulating layer, injecting fluorine ions into the second gate insulating layer, and diffusing the fluorine ions into the first gate insulating layer.

According to embodiments, the first gate insulating layer includes an oxide layer formed 1 nm or below by thermal oxidation process. According to embodiments, the first gate insulating layer may be nitrified by plasma nitrification process.

According to embodiments, the plasma nitrification process may be carried out by setting plasma power to 150˜200 W and supplying nitrogen of 10˜20% content for 100˜150 seconds. According to embodiments, curing may be carried out on the nitrified first gate insulating layer and the curing may be carried out by annealing process at 1,000˜1,015° C. for 8˜10 seconds.

According to embodiments, the second gate insulating layer may be formed 2 nm thick or below by ALD (atomic layer deposition) process. According to embodiments, the second gate insulating layer may be formed of a high dielectric constant insulator including at least one of HFO₂ and Al₂O₃.

According to embodiments, the fluorine ions may be injected into the second gate insulating layer using fluorine gas by annealing process at 400˜500° C. According to embodiments, the fluorine ions may be diffused to an interface with the first gate insulating layer.

### DRAWINGS

FIGS. 1A to 1C are cross-sectional diagrams illustrating a method of fabricating a MOSFET (Metal-Oxide Semiconductor Field Effect Transistor) according to embodiments.

FIG. 2 is a cross-sectional diagram of a MOSFET (Metal-Oxide Semiconductor Field Effect Transistor) according to embodiments.

### DESCRIPTION

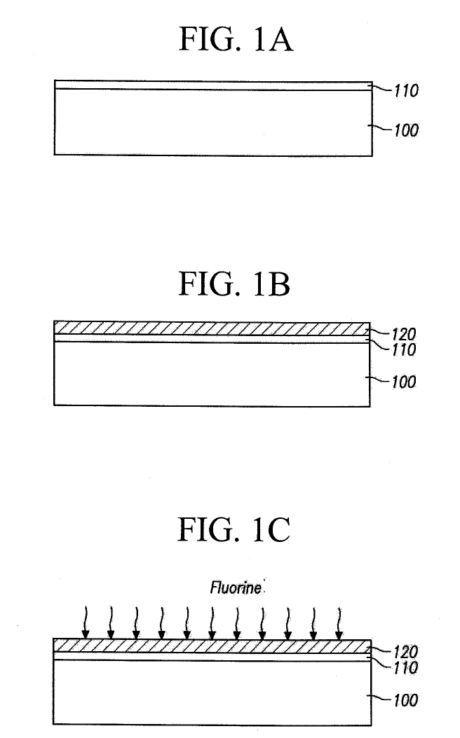

Referring to FIG. 1A, first gate insulating layer 110 may be formed by growing a silicon oxide (SiO₂) layer, for example by carrying out thermal oxidation process on semiconductor substrate 100 of silicon. In doing so, first gate insulating layer 110 of SiO₂ may be formed to be approximately 0˜1 nm thick over the substrate 100. This may prevent a later formed high-k isolating layer from coming into contact with silicon (Si), and from reacting when forming the high-k isolating layer including HfO₂ on substrate 100.

A plasma nitrification process may be carried out on first gate insulating layer 110. In embodiments, the plasma nitrification process may be carried out by setting plasma power to 150˜200 W and supplying nitrogen of 10˜20% content for 100˜150 seconds. In embodiments, a ratio of silicon to nitrogen may be set to 8˜10:1. This process condition may be adjustable according to a thickness of the oxide layer of SiO₂ or nitrogen concentration.

In embodiments, EOT (electrical oxide thickness) may be further reduced by the plasma nitrification process. Since nitrogen may be included in the oxide layer of SiO₂, a dielectric constant may be raised, which may enable the thickness of the oxide layer to be reduced.

A curing may be performed on first gate insulating layer 110 by annealing for approximately 8˜10 seconds at approximately 1,000˜1,015° C. The curing may performed to recover damage caused by the plasma nitrification process.

Referring to FIG. 1B, second gate insulating layer 120 having a high dielectric constant (high-k) on first gate insulating layer 110 having undergone the plasma nitrification process. In embodiments, second gate insulating layer 120 may be formed by an ALD (atomic layer deposition) process and formed 2-3 nm thick using a high-k such as HfO₂ and Al₂O₃. In embodiments, second gate insulating layer 120 may be formed of a high-k belong to HfO₂ series.

Referring to FIG. 1C, while the stacked gate insulating layer including first and second gate insulating layers 110 and 120 may be formed on the silicon substrate 100, an annealing process may be carried out and may inject fluorine gas into second gate insulating layer 120. In embodiments, the annealing may be carried out at approximately 400˜500° C. for approximately 50˜60 minutes.

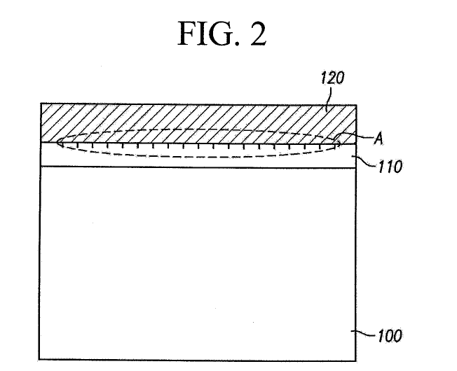

In embodiments, diffusion may be sufficiently carried out to enable the fluorine gas to be injected into an interface between second gate insulating layer 120 and first gate insulating layer 110 of SiO₂ beneath second gate insulating layer 120. In embodiments, a location of the injected fluorine gas is shown in FIG. 2.

Referring to FIG. 2, the fluorine gas may be located at the interface (A) between first gate insulating layer 110 of SiO₂ and second gate insulating layer 120 of HfO₂. In embodiments, it may be possible to effectively enhance the reduction of the speed of carrier mobility due to traps at the interface (A). Hence, the reliability of the gate insulating layer and the device performance may be enhanced.

According to embodiments, certain effects or advantages may be achieved. For example, by injecting fluorine gas into an interface between the first and second gate insulating layers, the embodiments may prevent carrier mobility from being reduced by traps.

Moreover, the reliability of a gate insulating layer and device capacity may be enhanced.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
forming a first gate insulating layer over a semiconductor substrate;
nitrifying the first gate insulating layer;
forming a second gate insulating layer over the first gate insulating layer; and
injecting fluorine ions into the second gate insulating layer.

2. The method of claim 1, further comprising diffusing the fluorine ions into the first gate insulating layer.

3. The method of claim 2, wherein the first gate insulating layer comprises an oxide layer formed at a thickness of 1 nm or less by a thermal oxidation process.

4. The method of claim 2, wherein the first gate insulating layer is nitrified by plasma nitrification process.

5. The method of claim 4, wherein the plasma nitrification process is performed using a plasma power of 150˜200 W and supplying nitrogen of 10˜20% content for 100˜150 seconds.

6. The method of claim 2, wherein the fluorine ions are injected into the second gate insulating layer using fluorine gas by an annealing process at 400˜500° C.

7. The method of claim 2, wherein the fluorine ions are diffused to an interface between the first and second gate insulating layers.

8. The method of claim 2, further comprising performing a curing process on the nitrified first gate insulating layer, wherein the curing is performed by annealing at 1,000˜1,015° C. for 8˜10 seconds.

9. The method of claim 1, wherein the second gate insulating layer is formed to be 2 nm thick or less by an atomic layer deposition (ALD) process.

10. The method of claim 1, wherein the second gate insulating layer comprises a high dielectric constant (high-k) insulator including at least one of HFO₂ and Al₂O₃.

11. A device, comprising:
a first gate insulating layer over a semiconductor substrate, the first gate insulating layer having been nitrified by a plasma nitrification process; and
a second gate insulating layer injected with fluorine ions over the first gate insulating layer, wherein the fluorine ions are diffused into the first gate insulating layer.

12. The device of claim 11, wherein the second gate insulating layer comprises a high dielectric constant.

13. The device of claim 12, wherein a ratio of silicon to nitrogen in the first gate insulating layer is approximately 8˜10:1.

14. The device of claim 12, wherein the first insulating layer is formed to have a thickness of approximately 1 nm or less, and wherein the second insulating layer is formed to have a thickness of approximately 2˜3 nm.

15. The device of claim 12, wherein the second gate insulating layer comprises one of HFO₂ and Al₂O₃.

16. The device of claim 12, wherein the second gate insulating layer is formed by an atomic layer deposition (ALD) process.

17. The device of claim 12, wherein the second gate insulating layer has been annealed by injecting fluorine gas into the second gate insulating layer.

18. The device of claim 12, further comprising fluorine gas injected between the first gate insulating layer and the second gate insulating layer.

19. The device of claim 18, wherein fluorine ions from the fluorine gas are diffused to an interface between the first and second gate insulating layers.
